(19) United States
(12) Patent Application Publication
(10) Pub. No.: US 2007/0215993 A1
(43) Pub. Date: Sep. 20, 2007

(54) Chip Package Structure

(75) Inventor: Sheng-Hsiung Chen, Kaohsiung Shih (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: ADVANCED SEMICONDUCTOR ENGINEERING INC., Kaohsiung (TW)

(21) Appl. No.: 11/618,041

(22) Filed: Dec. 29, 2006

(30) Foreign Application Priority Data
Mar. 16, 2006 (TW) 95108948

(51) Int. Cl. H01L 23/495

(52) U.S. Cl. 257/675

(57) ABSTRACT

A chip package structure including a carrier, a chip, first bonding wires, second bonding wires, and an encapsulant is provided. The carrier has first contacts and at least one second contact, and the chip has at lease one first bonding pad and at least one second bonding pad. In addition, the first bonding wire electrically connects the first bonding pad and the first contact, and the second bonding wire electrically connects the second bonding pad and the second contact, wherein each of the first bonding pads electrically connects at least two first contacts through at least two first bonding wires, and each second bonding pad electrically connects the second contact through one single second bonding wire. Further, the encapsulant is disposed on the carrier to encapsulate the chip, the first bonding wires, and the second bonding wires.

### RELATED APPLICATIONS

The present application is based on, and claims priority from, Taiwan Application Serial Number 95108948, filed Mar. 16, 2006, the disclosure of which is hereby incorporated by reference herein in its entirety.

### FIELD OF THE INVENTION

The present invention relates to a chip package structure, and more particularly, to the chip package structure with wire bonding.

### BACKGROUND OF THE INVENTION

Recently, with the advances of the electronic technologies and semiconductor industries, the electronic products with more user-friendly designs and better functions are continuously presented to the market, and are developed toward lightness, thinness, shortness and smallness. In the semiconductor industries, the production of integrated circuits (IC) is mainly divided into three stages: IC design, IC fabrication and IC packaging. In the IC packaging, bare chips are made via the steps of wafer fabrication, circuit design, photomask fabrication and wafer cutting, and each bare chip formed by wafer cutting is electrically connected to a package substrate via bonding pads formed thereon, and then an encapsulant is used to encapsulate the bare chip, thereby preventing the bare chip from being affected by the ambient moisture and contaminated by dust; and providing media for electrically connecting the bare chip to the external circuit, thus forming a chip package structure.

Simultaneously referring to FIG. 1A and FIG. 1B, FIG. 1A is a schematic diagram showing a conventional chip package structure; and FIG. 1B is a schematic top view illustrating the conventional chip package structure shown in FIG. 1A. A chip package structure 100a comprises a carrier 110, a chip 120, a plurality of bonding wires 130 and an encapsulant 140, wherein the chip 100 is disposed on a surface of the carrier 110, and a plurality of bonding pads 122 on the chip 120 are electrically connected to a plurality of contacts 112 located on the carrier 110 via wire-bonding. Besides, the encapsulant 140 is also disposed on the surface of the carrier 110, and encapsulates the contacts 112, the chip 120 and a plurality of bonding wires 130 between the contacts 112 and the bonding pads 122, thereby preventing the chip 120 from being affected by the ambient (such as moisture and dust, etc.), and protecting the bonding wires 130 from being damaged by external force. Further, the carrier 110 has a plurality of conductive wires 102, wherein the conductive wires 102 are connected between the contacts 112a and the contacts 112b respectively. However, when the conductive wire 102 is broken or has an error occurring in the wiring layout, the electrically connection between the contact 112a and the contact 112b will be interrupted, i.e. the contact 112b fails to receive the output signal from the chip 120 via the contact 112a. Hence, the carrier 110 loses its original efficacy.

Then, referring to FIG. 2, FIG. 2 is a schematic top view illustrating another conventional chip package structure. Such as shown in FIG. 1B and FIG. 2, the chip package structure 100b is similar to the aforementioned chip package structure 100a, but the main difference therebetween resides in that: the positions of the contacts 112 on the carrier 110 and those of the bonding pads 122 on the chip 120 are different between the chip package structures 100a and 100b, for example, in the chip package structure 100b, a contact 112c is disposed on another position instead of the contact 112b disposed on the chip package structure 100a. In the chip package structure 100b, for meeting the requirements of the wiring layout, a conductive wire 104 is used to electrically connect the contact 112a to the contact 112c. However, the contact 112a and the contact 112c are disposed on the carrier 110 respectively and are corresponding to both sides of the chip 120, i.e. it is more difficult to implement the conductive wire 104 than to implement the conductive wire 102 as shown in FIG. 1B with respect to the wiring layout. In other words, the conductive wire 104 is more likely to be broken or have an error occurring in the wiring layout, thus resulting in the failure of the carrier 110. Hence, it is an important issue regarding how to maintain the electrical connection between the contacts whenever the conductive wire is broken or there is an error occurring in the wiring layout of the conductive wire.

### SUMMARY OF THE INVENTION

In view of the foregoing, it is an aspect of the present invention to provide a chip package structure for maintaining the original efficacy when the conductive wire in the carrier is broken or there is an error occurring in the wiring layout of the conductive wire.

According to the aforementioned aspect of the present invention, the present invention provides a chip package structure comprising a carrier, a chip, a plurality of first bonding wires, at least one second bonding wire and an encapsulant, wherein the carrier has a plurality of first contacts and at least one second contact, and the chip has at least one first bonding pad and at least one second bonding pad. Further, a plurality of first bonding wires electrically connect the first bonding pad to the first contacts, and the at least one second bonding wire electrically connects the second bonding pad to the second contact, wherein the first bonding pad is electrically connected to at least two of the first contacts via at least two of the first bonding wires, and the second bonding pad is electrically connected to a second contact via a second bonding wire. Further, the encapsulant is disposed on the carrier to encapsulate the chip, the first bonding wires, and the at least one second bonding wire.

According to a preferred embodiment of the present invention, the carrier can be such as a wiring substrate, and the first contacts and the second contacts can be such as a plurality of connecting pads respectively.

According to another preferred embodiment of the present invention, the carrier can be such as lead frame, and the first contacts and the second contacts can be such as a plurality of leads respectively.

According to another preferred embodiment of the present invention, each of the first bonding wires comprises a thumbtack-shaped bump, and a third bonding-wire having a wedge-shaped end, wherein the wedge-shaped end is connected onto the thumbtack-shaped bump. Further, the thumbtack-shaped bumps of the first bonding wires can be for example mutually stacked on the first bonding pad, and the material forming the thumbtack-shaped bump comprises gold.

The embodiments of the present invention further provide a chip package structure comprising a plurality of bonding wires and the aforementioned carrier, chip and encapsulant. The bonding wires electrically connect the bonding pads to the contacts, wherein at least one of the bonding pads is electrically connected to at least two of the contacts via at least two of the bonding wires.

In accordance with the above, in the chip package structure of the embodiments of the present invention, at least one bonding pad is connected to at least two contacts via at least two bonding wires, so that whenever the conductive wire is broken or there is an error occurring in the wiring layout of the conductive wire, the electrical connections between the bonding pad and the contacts still can be maintained, thus enabling the chip package structure to keep its original efficacy.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A is a schematic diagram showing a conventional chip package structure;

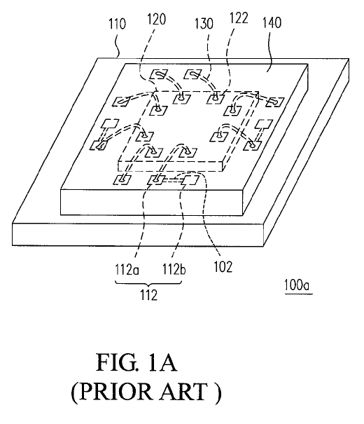

FIG. 1B is a schematic top view illustrating the conventional chip package structure shown in FIG. 1A;

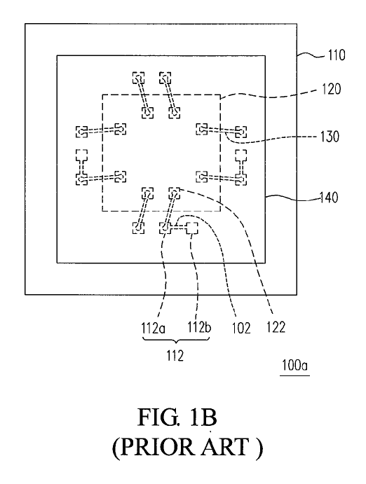

FIG. 2 is a schematic top view illustrating another conventional chip package structure;

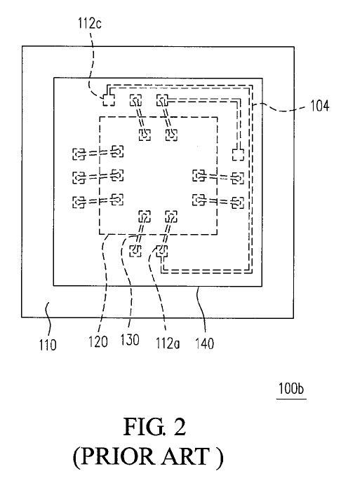

FIG. 3A is a schematic diagram showing a chip package structure according to a first embodiment of the present invention;

FIG. 3B is a schematic top view illustrating the chip package structure shown in FIG. 3A;

FIG. 3C is a schematic diagram showing the structure of the first boding wires shown in FIG. 3A;

FIG. 4 is a schematic top view illustrating a chip package structure according to a second embodiment of the present invention; and

FIG. 5 is a schematic top view illustrating a chip package structure according to a third embodiment of the present invention.

### DETAILED DESCRIPTION OF THE PREFERRED EMBODIMENTS

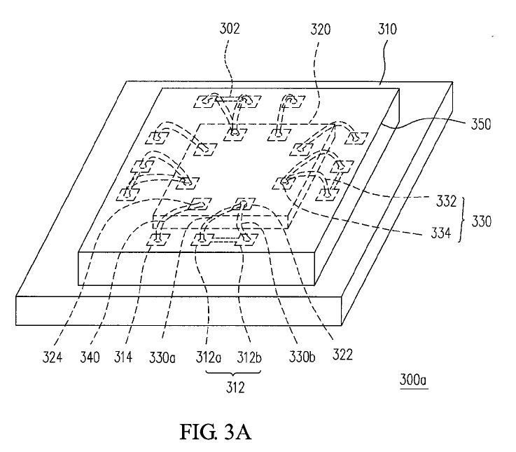

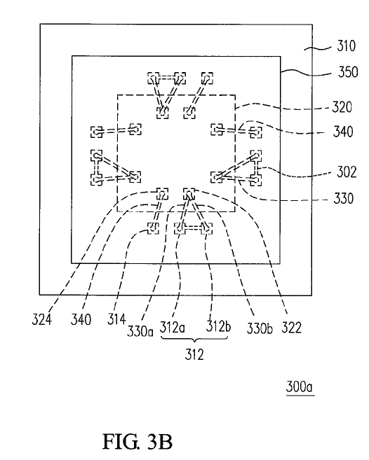

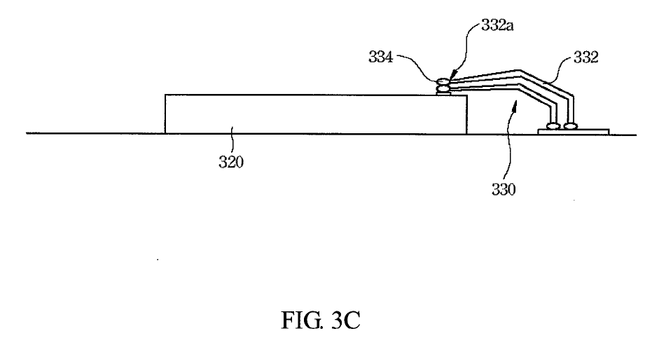

Simultaneously referring FIG. 3A and FIG. 3B, FIG. 3A is a schematic diagram showing a chip package structure according to a first embodiment of the present invention; and FIG. 3B is a schematic top view illustrating the chip package structure shown in FIG. 3A. Such as shown in FIG. 3A and FIG. 3B, a chip package structure 300a comprises a carrier 310, a chip 320, a plurality of first bonding wires 330 (such as a first bonding wire 330a and a first bonding wire 330b), at least one second bonding wire 340 and an encapsulant 350, wherein the chip 320 is for example disposed on the carrier 310, and the encapsulant 350 is also disposed on the carrier 310 for encapsulating the chip 320, the first bonding wires 330, and the second bonding wire 340, thereby preventing the chip 320 from being affected by the ambient (such as moisture and dust, etc.), and protecting the first bonding wires 330 and the second bonding wires 340 from being damaged by external force.

Further, the carrier 310 has a plurality of first contacts 312 (such as a first contact 312a and a first contact 312b), and one or more second contacts 314, and the chip 320 has one or more first bonding pads 322 and one or more second bonding pads 324. Further, the first bonding wires 330 are use for electrically connecting the first bonding pad 322 to the first contacts 312, and the second bonding wire 340 is used for electrically connecting the second bonding pad 324 to the second contact 314. In this embodiment, in the carrier 310, for example, there are a plurality of conductive wires 302, wherein for example, the conductive wire 302 is electrically connected between the first contact 312a and the first contact 312b, and the first bonding pad 322 has the first bonding wire 330a and the first bonding wire 330b respectively connected to the first contact 312a and the first contact 312b, i.e. the first bonding pad 322 is electrically connected to two or more first contacts 312 via two or more first bonding wires 330. The second pad 324 is connected to one second contact 314 via one second bonding wire 340.

Hence, it can be known from the above description that: when the conductive wire 302 connected between the first contact 312a and the first contact 312b are broken or there is an error occurring in the wiring layout of the conductive wire 302, the first contact 312a and the first contact 312b still can be electrically connected via the first bonding wire 330a and the first bonding wire 330b, thus continuously maintaining the electrical connection between the first contact 312a and the first contact 312b. Further, the carrier 310 of the present embodiment still can be a wiring substrate, and the first contacts 312 and the second contacts 314 disposed thereon are such as a plurality of connecting pads.

Referring to FIG. 3C, FIG. 3C is a schematic diagram showing the structure of the first boding wires 330 shown in FIG. 3A. According to the above description, in order to understand the connecting relationship between the aforementioned first bonding wires 330 and first bonding pad 322, wherein each of the first bonding wires 330 comprises a thumbtack-shaped bump 334; and a third bonding-wire 332 having a wedge-shaped end 332a connected onto the thumbtack-shaped bump, the detailed description is provided hereinafter. Referring to FIG. 3A, the wire-bonding method of the present embodiment is such as forming the thumb-stack shaped bump 334 on the first bonding pad 322; then using a wire bonder to wire bond a the third bonding-wire 332 onto the first contact 312; then pulling the third bonding-wire 332 upwards for a predetermined distance by the wire bonder; and thereafter turning the wedge-shaped end 332a of the third bonding-wire 332 towards the thumb-stack shaped bump 334 pre-formed on the first bonding pad 322, wherein the material forming the third bonding-wire 332 and the thumb-stack shaped bump 334 is such as gold. Thus, when the wire binder is desired to repeat forming the first bonding wires 330 between the first bonding pad 322 and the first contact 312, the thumb-stack shaped bumps 334 of the respective first bonding wires are mutually stacked on the first bonding pad 322. The wire-bonding method described above will allow the wire bonder to successfully keep way from the other bonding wires completed or the chip 320 while the wire bonder is in operation.

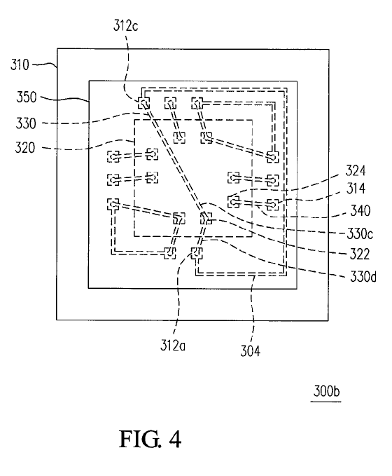

Thereafter referring to FIG. 4, FIG. 4 is a schematic top view illustrating a chip package structure according to a second embodiment of the present invention. Simultaneously referring FIG. 3B and FIG. 4, the chip package structure 300b of the present embodiment is similar to the aforementioned chip package structure 300a, but the main difference therebetween resides in that: the positions of the contacts on the carrier 310 and those of the bonding pads 122 on the chip 120 are different between the chip package structures 300a and 300b, for example, in the chip package structure 300b, a contact 312c is disposed on another position instead of the contact 312b disposed on the chip package structure 300a. In the chip package structure 300b, for example, for meeting the requirements of the wiring layout, a conductive wire 304 is used to electrically connect the contact 312a to the contact 312c, and the contact 312a and the contact 312c are disposed on the carrier 310 respectively and are corresponding to both sides of the chip 320, i.e. it is more difficult to implement the conductive wire 304 than to implement the conductive wire 302 in the chip package structure 300a with respect to the wiring layout. In the present embodiment, the first bonding pad 322 can be electrically connected to the first contact 312c and the first contact 312a respectively via a first bonding wire 330c and a first bonding wire 330d. In other words, when the conductive wire 304 between the first contact 312c and the first contact 312a is broken or there is an error occurring in the wiring layout of the conductive wire 304, the electrical connection between the first contact 312c and the first contact 312a still can be maintained via the first bonding wire 330c and the first bonding wire 330d.

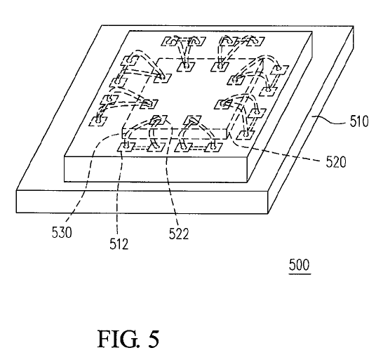

The aforementioned chip package structures 300a and 300b use the first bonding wire 330 to electrically connect the first contact 312 and the first binding pad 322; and use the second binding wire 349 to electrically connect the second contact 314 to the second bonding pad 324. It is worthy to be noted that, in another chip package structure, a bonding wire can be used to electrically connect a contact on a carrier to a bonding pad on a chip. FIG. 5 is a schematic top view illustrating a chip package structure according to a third embodiment of the present invention. Simultaneously referring to FIG. 3 and FIG. 5, the chip package structure 500 is similar to the chip package structure 300a of the first embodiment, but the main difference therebetween resides in that: the chip package structure 500 of the present embodiment merely uses a bonding wire 530 to electrically connect a contact 512 on a carrier 510 to a bonding pad 533 on a chip 520, and thus the chip packaging process for the chip package structure 500 is relatively simple.

To sum up, in a chip package structure shown in the embodiments of the present invention, a bonding pad on a chip can be electrically connected to various contacts on a carrier via a plurality of bonding wires, wherein each of the bonding wires is connected to the bonding pad via its thumbtack-shaped bump. In comparison with the conventional skill, the present invention has the following advantages:

(1) When a conductive wire in the carrier for connecting two contacts thereon is broken or an error occurs in the wiring layout of the conductive wire, the method for connecting the bonding wires in the chip package structure of the present invention can make the relationship of electrical connection between those two contacts being maintained;

(2) When the conductive wire between two contacts on the carrier has relatively high difficulty level with respect to the wiring layout, the method for connecting the bonding wires in the chip package structure of the present invention can simplify the electrical connection between those two contacts; and

(3) In the chip package structure of the present invention, the thumbtack-shaped bump of the respective bonding wires are mutually stacked on one bonding pad, whereby the wire boner can successfully keep way from the chip or the bonding wires completed while in operation.

According to the aforementioned preferred embodiments, one advantage of the substrate structure and the method for manufacturing the same is to manufacture an substrate structure having an identification mark fabricated thereon, in which the identification mark is at least one hole designed to be formed on the surface dielectric layer but not encapsulated with the surface circuit layer, for forming an indentation on the solder mask of the substrate structure as an identification mark for identifying the substrate unit, by using the prior process equipments instead of changing the existing prior process flow of the substrate structure. Therefore, in comparison with the conventional method for manufacturing the substrate structure, the method disclosed by the present invention, which is almost the same with the prior method for manufacturing the same, instead of changing the existing prior process flow, can manufacture the substrate structure having the identification mark, thereby increasing the product quality and process yield.

As is understood by a person skilled in the art, the foregoing preferred embodiments of the present invention are illustrated of the present invention rather than limiting of the present invention. It is intended to encapsulate various modifications and similar arrangements included within the spirit and scope of the appended claims. Therefore, the scope of which should be accorded the broadest interpretation so as to encompass all such modifications and similar structure.

What is claimed is:

1. A chip package structure, comprising:
a carrier having a plurality of first contacts and at least one second contact;
a chip having at least one first bonding pad and at least one second bonding pad;
a plurality of first bonding wires electrically connecting the first bonding pad to the first contacts, wherein the first bonding pad is electrically connected to at least two of the first contacts via at least two of the first bonding wires;
at least one second bonding wire electrically connecting the at least one second bonding pad to the second contact, wherein the second bonding pad is electrically connected to a second contact via one of the at least one second bonding wire; and
an encapsulant disposed on the carrier to encapsulate the chip, the first bonding wires, and the at least one second bonding wire.

2. The chip package structure according to claim 1, wherein the carrier is a wiring substrate, and the first contacts and the second contacts are a plurality of connecting pads respectively.

3. The chip package structure according to claim 1, wherein the carrier is lead frame, and the first contacts and the second contacts are a plurality of leads respectively.

4. The chip package structure according to claim 1, wherein each of the first bonding wires comprises:
a thumbtack-shaped bump; and
a third bonding-wire having a wedge-shaped end connected onto the thumbtack-shaped bump.

5. The chip package structure according to claim 4, wherein the thumbtack-shaped bump and the wedge-shaped end of the third bonding-wire are mutually stacked on the first bonding pad.

6. The chip package structure according to claim 4, wherein the material forming the thumbtack-shaped bump comprises gold.

7. The chip package structure according to claim 4, wherein the material forming the wedge-shaped end of the third bonding-wire comprises gold.

8. A chip package structure, comprising:
a carrier having a plurality of contacts;
a chip having a plurality of bonding pads;
a plurality of first bonding wires electrically connecting the bonding pads to the contacts, wherein at least one of the bonding pads is electrically connected to at least two of the contacts via at least two of the first bonding wires; and
an encapsulant disposed on the carrier to encapsulate the chip and the first bonding wires.

9. The chip package structure according to claim 8, wherein the carrier is a wiring substrate, and the contacts are a plurality of connecting pads respectively.

10. The chip package structure according to claim 8, wherein the carrier is lead frame, and the contacts are a plurality of leads respectively.

11. The chip package structure according to claim 8, wherein each of the first bonding wires comprises:
a thumbtack-shaped bump; and
a third bonding-wire having a wedge-shaped end connected onto the thumbtack-shaped bump.

12. The chip package structure according to claim 11, wherein the thumbtack-shaped bump and the wedge-shaped end of the third bonding-wire are mutually stacked on the bonding pad.

13. The chip package structure according to claim 11, wherein the material forming the thumbtack-shaped bump comprises gold.

14. The chip package structure according to claim 11, wherein the material forming the wedge-shaped end of the third bonding-wire comprises gold.
